(19) United States
(12) Patent Application Publication
(10) Pub. No.: US 2019/0088790 A1
(43) Pub. Date: Mar. 21, 2019

(54) PLANARISATION LAYERS

(71) Applicant: Flexenable Limited, Cambridge (GB)

(72) Inventors: Matthew James Harding, Cambridge (GB); Mike Banach, Cambridge (GB)

(73) Assignee: Flexenable Limited, Cambridge (GB)

(21) Appl. No.: 16/134,262

(22) Filed: Sep. 18, 2018

Related U.S. Application Data
(62) Division of application No. 14/913,764, filed on Feb. 23, 2016, now abandoned.

(30) Foreign Application Priority Data
Aug. 23, 2013 (GB) 1315081.8

(51) Int. Cl. H01L 29/786; G06F 3/041; G06F 3/044; H01L 27/12; G02F 1/1368; G02F 1/1362; G02F 1/1333

(52) U.S. Cl. CPC H01L 29/78633; G06F 3/0412; G06F 3/044; H01L 27/1218; G02F 1/1368; G06F 2203/04103; H01L 29/78648; H01L 27/1259; G02F 1/136209; G02F 1/136286; G02F 1/13338; H01L 29/78603

(57) ABSTRACT

A device, comprising: an unplanarised plastic substrate; an electrically and/or optically functional layer formed on the unplanarised substrate; a planarisation layer formed over the functional layer; at least a first conductor layer and a semiconductor layer formed over the planarization layer, wherein the first conductor layer defines at least source and drain electrode circuitry for one or more transistor devices, and the semiconductor layer defines semiconductor channels for said one or more transistor devices.

### CROSS REFERENCE TO RELATED APPLICATIONS

This is a Divisional of application Ser. No. 14/913,764 filed Feb. 23, 2016, claiming priority based on International Application No. PCT/EP2014/067842 filed Aug. 21, 2014, claiming priority based on British Patent Application No. 1315081.8 filed Aug. 23, 2013, the contents of all of which are incorporated herein by reference in their entirety.

Planarisation layers are used in the field of electronic devices to prepare unplanarised surfaces (such as e.g. the surface of a plastic substrate or a metal foil substrate) for the formation of a functional layer of the electronic device such as the patterned conductive layer defining electrical circuitry of the electronic device.

The surface roughness of unplanarised plastic and metal foil substrates was thought to render them unsuitable for directly supporting any functional layer of an electronic device; and the conventional approach has been to planarise the surface of the unplanarised substrate before forming any functional layer of the electronic device.

The inventors for the present invention have identified the challenge of developing functional layers that can be interposed between the planarisation layer and the unplanarised substrate that the planarisation layer serves to planarise.

The present invention provides a device, comprising: a substrate; a planarisation layer that functions to planarise the substrate; at least a first conductor layer and a semiconductor layer formed over the planarization layer, wherein the first conductor layer defines at least source and drain electrode circuitry for one or more transistor devices, and the semiconductor layer defines semiconductor channels for said one or more transistor devices; and an additional, functional layer between the substrate and the planarisation layer.

There is also provided a device, comprising: an unplanarised plastic substrate; an electrically and/or optically functional layer formed on the unplanarised substrate; a planarisation layer formed over the functional layer; at least a first conductor layer and a semiconductor layer formed over the planarization layer, wherein the first conductor layer defines at least source and drain electrode circuitry for one or more transistor devices, and the semiconductor layer defines semiconductor channels for said one or more transistor devices.

According to one embodiment, the functional layer exhibits a smaller transmittance than the substrate and planarization layer for light of a wavelength that degrades the semiconductor channels.

According to one embodiment, said light of a wavelength that degrades the semiconductor channels includes visible light; said device further comprises a backlight on the other side of the substrate to the functional layer for the transmission of visible light to optical media located on the opposite side of the semiconductor channels to the backlight and controlled by the transistor devices; and said functional layer is patterned so as to allow the transmission of visible light from the backplane to said optical media in regions other than the semiconductor channels.

According to one embodiment, said optical media is a liquid crystal optical media.

According to one embodiment, the functional layer comprises a second conductor layer which extends beneath at least a portion of the drain electrode circuitry for each of said one or more transistors, and is capacitively coupled to the drain electrode circuitry via the planarization layer.

According to one embodiment, said second conductor layer comprises an array of conductor islands, each connected within the second conductor layer to all neighbouring conductor islands.

According to one embodiment, each conductor island corresponds substantially in location to at least a portion of the drain electrode circuitry for a respective transistor.

According to one embodiment, said second conductor layer is formed from a mesh of interconnecting conductive filaments.

According to one embodiment, the additional layer comprises a second conductor layer providing gate electrodes for each of the transistor devices.

According to one embodiment, said second conductor layer is patterned into an array of independently addressable gate lines, each gate line extending under the semiconductor channels of a respective column of transistors and comprising a mesh of conductive filaments.

According to one embodiment, said second conductor layer is patterned into an array of islands each isolated from other islands within said second conductor layer, and each island is addressable via one of a plurality of addressing lines extending over the planarization layer.

According to one embodiment, the device further comprises a third conductor layer formed over the planarization layer on the opposite side of the first conductor layer to the second conductor layer, which third conductor layer defines gate electrode circuitry for said array of transistor devices.

There is also hereby provided a method of operating a device as described above, comprising: controlling the voltage applied to said gate electrodes defined by the second conductor layer so as to mitigate stress induced in the semiconductor channels by the operation of the gate electrode circuitry.

According to one embodiment, the method comprises: using said gate electrodes defined by the second conductor layer to tune the threshold voltage of the transistor devices, and using said gate electrode circuitry to switch the transistor devices.

According to one embodiment, the functional layer comprises a second conductor layer between the substrate and the planarization layer; said one or more transistor devices constitute the control circuitry for a display device; and said second conductor layer forms the bottom conductor of a touch sensor mechanism for said display device.

According to one embodiment, said additional layer comprises a patterned second conductor layer formed from a mesh of interconnecting conductive filaments.

There is also hereby provided a method comprising: providing an unplanarised substrate; forming an electrically and/or optically functional layer on the unplanarised substrate; forming a planarisation layer over the functional layer; and forming a first conductor layer and a semiconductor layer over the planarization layer, wherein the first conductor layer defines at least source and drain electrode circuitry for one or more transistor devices, and the semiconductor layer defines semiconductor channels for said one or more transistor devices.

According to one embodiment of the method, the functional layer is a patterned layer.

According to one embodiment of the above-described device and method, the unplanarised substrate has a surface roughness R_{A} greater than 5 nm. In another embodiment, the unplanarised substrate has a surface roughness R_{A} greater than 10 nm, and in yet another embodiment the unplanarised substrate has a surface roughness R_{A} greater than 15 nm. Surface roughness R_{A} is a commonly used profile roughness parameter described in detail at Section 3.2.1.1 of “Surfaces and their Measurement” by David Whitehouse and published by Taylor & Francis Books, Inc. Surface roughness R_{A} characterises the surface based on the vertical deviations of the roughness profile from the mean line, and is the arithmetic average of the absolute values (magnitudes) of the vertical deviations. In one embodiment, the unplanarised plastic substrate is characterised by the existence of surface scratches and/or other surface defects.

Embodiments are described in detail hereunder, by way of example only, with reference to the accompanying drawings, in which:

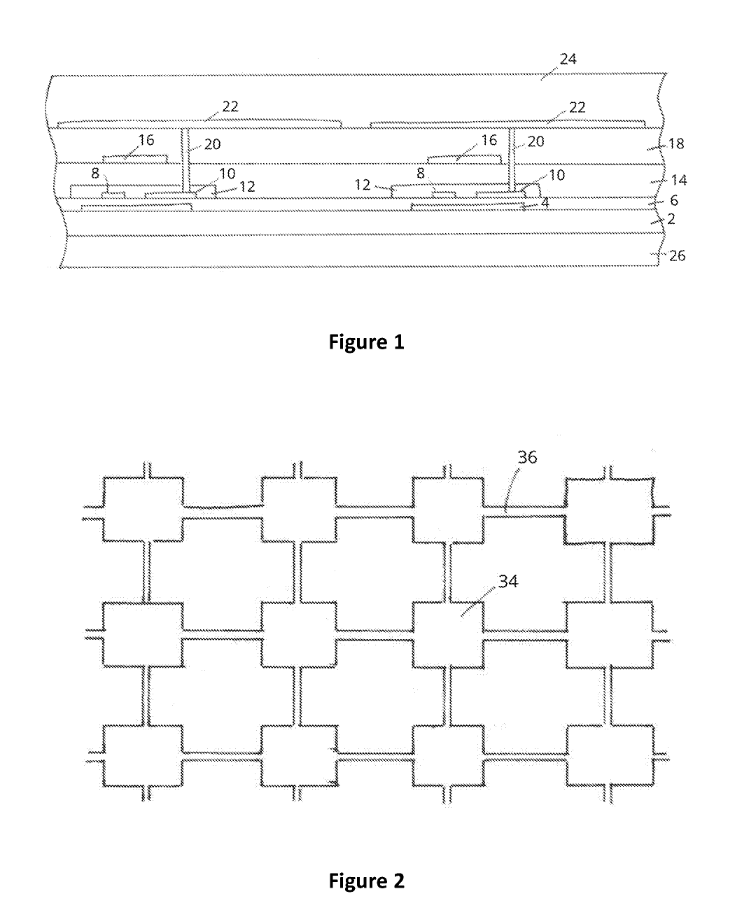

FIG. 1 illustrates a technique according to a first embodiment of the present invention; and

FIG. 2 illustrates an example of a conductive layer pattern for a technique according to a second embodiment of the present invention.

FIG. 1 illustrates an example of a display device according to a first embodiment of the present invention. A flexible plastic substrate 2 (e.g. PET or PEN substrate) supports a plurality of top-gate thin film transistors (TFTs) each comprising a source electrode 8 and a drain electrode 10 connected by a semiconductor channel (provided by a patterned semiconductor layer 12), and a gate electrode 16 coupled to the semiconductor channel via a gate dielectric 14. The conductor layer defining the source electrodes 8 and drain electrodes 10 also defines: a set of source addressing lines (not shown) each connecting the source electrodes 8 of a respective row of TFTs to a respective terminal at the edge of the TFT array; and extended drain conductors, each drain conductor serving as a conductive connection to a location outside the coverage of the gate electrode 16 for a vertical interlayer connection 20 to an overlying pixel electrode 22 for the respective TFT. The gate electrodes 16 are provided as an array of parallel gate lines 16 extending perpendicularly to the above-mentioned source addressing lines, and each gate line 16 provides the gate electrodes for a respective column of TFTs. The gate lines 16 are isolated from the overlying pixel electrodes 22 via an insulator layer 18. The patterned conductor layer defining the gate lines 16 may also define other elements, such as COM lines (not shown) which extend parallel to the gate lines 16 and form pixel capacitors with the pixel electrodes 22.

The patterned conductor layer defining the source and drain electrodes 8, 10, source addressing lines and extended drain conductors is formed on the plastic substrate 2 via a planarisation layer 6. The planarisation layer 6 planarises the upper surface of the plastic substrate 2 (i.e. it is the first layer to provide an upper surface of significantly lower surface roughness than that of the upper plastic surface of the plastic substrate), and ensures a surface of good quality for deposition of the source addressing lines etc. even with the existence of surface scratches, surface roughness and other surface defects at the upper plastic surface of the plastic substrate 2. The surface roughness R_{A} of the upper surface after deposition of the substrate planarisation layer is typically less than 2 nm, and preferably less than 1 nm. A technique according to one embodiment of the present invention involves providing a patterned conductor on the plastic substrate 2 before the deposition on the plastic substrate of any planarisation layer to planarise the plastic substrate 2. The patterned conductor layer provided directly on the unplanarised plastic substrate 2 may define an array of light-shielding lines 4. Each light-shielding line 4 extends parallel to a respective gate line 16, is substantially centred on the respective gate line, and is of greater width than the respective gate line such that each gate line 16 lies wholly within the footprint of the respective light-shielding line 4, even allowing for some degree of misalignment between the bottom conductor layer 4 and the upper conductor layer defining the gate line 16 during the production process. For example, the width of the light-shielding lines 4 may be about 10 or 15 microns greater than the gate line width. Good alignment between the light-shielding lines 4 and source/drain electrodes 8, 10 and the gate lines 16 can be achieved by defining alignment marks (fiducials) in the patterned conductor layer defining the light-shielding lines 4, and using these alignment marks as reference for the patterning of the upper conductor layers defining the source/drain electrodes and gate lines 16. Where the formation of these upper conductor layers involves the deposition of a blanket layer of opaque conductor material followed by patterning, the areas overlying the alignment marks are first temporarily masked to avoid the alignment marks being hidden by the blanket layers of opaque conductor material.

The provision of the light-shielding layer 4 is of particular use for display devices that rely on the transmission of light from a backlight 26 through the TFT array to an optical media 24 (such as a non-reflective liquid crystal media) controlled by the TFT array. The patterning of the light-shielding layer protects the semiconductor channels from degrading light emitted from the backlight whilst allowing the transmission of light from the backlight 26 to the optical media 24.

The light-shielding lines 4 may be made from any material that is more opaque to incident damaging radiation (e.g. visible light, UV light) than both the substrate 2 and the planarisation layer 6. Some examples of suitable materials are: gold, aluminium, copper, high performance copper alloys (HPC) commercially available as sputter target materials, advanced silver alloys (AMO) commercially available as sputter target materials, and silver. The thickness of the light-shielding lines 4 is selected according to the degree to which it is desired to protect the semiconductor channels from radiation.

One example of a technique for forming the light-shielding lines 4 involves forming a blanket layer of the light-shielding material on the plastic substrate 6 (by e.g. sputtering or other vapour deposition technique) before deposition of any planarisation layer on the plastic substrate, and then patterning the blanket layer by e.g. photolithography and etching.

Any possible discontinuities in the light-shielding lines resulting from defects at the plastic substrate surface are not fatal for the light-shielding function, because the light-shielding function for any TFT of the TFT array does not require an electrical connection to a terminal at the edge of the device.

The patterned light-shielding layer need not be formed of light-shielding lines extending between opposite edges of the TFT array. The patterned light-shielding layer may, for example, be formed of an array of isolated islands of light-shielding material, each island shielding the semiconductor channel of a respective transistor.

The light-shielding layer also need not be formed from a conductor material because a conductive path across the TFT array is not required for the purpose of shielding the semiconductor channels from damaging incident radiation. However, the provision of a conductor material directly on the unplanarised plastic substrate 2 (i.e. before deposition of any planarisation layer on the plastic substrate) and insulated from overlying conductor layers by the planarisation layer 6 can serve other functions with or without the light-shielding function.

For example, conductor elements between the plastic substrate 2 and the planarisation layer 6 (i.e. formed on the unplanarised plastic substrate before deposition of any planarisation layer) can form capacitors with the extended drain conductors and/or COM lines at the same level as the gate lines 16, and thereby facilitate the storage of charge on the pixel electrodes 22. This function may also be achieved by an unpatterned conductor layer between the plastic substrate 2 and the planarisation layer 6 (i.e. formed on the unplanarised plastic substrate before deposition of any planarisation layer).

Conductor elements 4 between the plastic substrate 2 and the planarisation layer 6 (i.e. formed on the unplanarised plastic substrate before deposition of any planarisation layer) can also provide second gate electrodes on the opposite side of the semiconductor channel to the gate lines 16. Such second gate electrodes may be useful for tuning the threshold voltage of the TFTs (i.e. the voltage to which the source electrode needs to be biased to achieve an electric potential at the drain electrode that causes a change in the output of the optical media for the associated pixel), or mitigating the effect of stress induced in the semiconductor channels by operation of the top gate electrodes. For example, the operation of a display device typically involves sequentially switching the gate lines into an on-state whilst keeping all other gate lines in an off-state. Keeping a gate line in an off-state can involve applying a voltage to the gate line, and throughout the period of time that any gate line is kept in an off-state (frame time), the continuous application of the off-voltage can induce polarisation effects within the gate dielectric and cause migration of mobile ions into and within the semiconductor channels. Such mobile ions have undesirable effects such as trapping charge and causing a change in the threshold voltage of the TFT, weakening the electric field created by the application of a voltage to the gate electrode, and chemically altering the semiconductor channel and/or gate dielectric. A second gate electrode on the opposite side of the semiconductor channel can be used to counteract and/or compensate for some of the undesirable effects described above. The second gate electrodes may be arranged as columns of conductors, each column aligned with a respective one of the gate lines 16, and providing a second gate electrode for the same column of TFTs as the respective gate line 16 with which it is aligned.

Columns or rows of addressable conductor elements between the plastic substrate 2 and the planarisation layer 6 (i.e. formed on the unplanarised plastic substrate before deposition of any planarisation layer) can also provide the lower conductor layer in a touch-sensor mechanism for a display device.

All these other functions require an electrical connection to a terminal at the edge of the TFT array for the application of a voltage. With reference to FIG. 2, one technique for better avoiding electrical discontinuities between the terminal and any conductor element between the plastic substrate 2 and the planarisation layer 6 (i.e. formed on the unplanarised plastic substrate before deposition of any planarisation layer) involves forming the conductor layer 4 on the plastic substrate 2 as an array of conductor islands 36, each conductor island 34 connected by links 36 within the patterned conductor layer 4 to all adjacent conductor islands (in both x and y directions). This technique is, for example, of particular use for: (i) forming conductor elements to form capacitors with the extended drain conductors and/or COM lines at the same level as the gate lines; and (ii) forming back gate electrodes whose function can be achieved simultaneously for all TFTs in the array.

Another technique involves forming the patterned conductor layer as an array of conductor islands 32 isolated from each other within the patterned conductor layer, and providing interlayer conductor connections through the planarisation layer 6 between each conductor island and one of an array of parallel conductor lines formed on the planarisation layer parallel to the source addressing lines, each conductor line connected to a respective row of islands and to a respective terminal at the edge of the TFT array. This technique is, for example, of particular use for: (i) forming conductor elements to form capacitors with the extended drain conductors and/or COM lines at the same level as the gate lines; and (ii) forming rows or columns of conductors for a touch sensor mechanism.

Another technique involves forming the conductor layer between the plastic substrate 2 and the planarisation layer 6 as a non-woven mesh of interconnecting conductive filaments, such as a non-woven mesh of metallic nanowires (e.g. silver nanowires). An array of conductor lines made from such a non-woven mesh is less prone to electrical discontinuities in any of the conductor lines because a non-woven mesh is more ductile than a sputtered metal layer, and flexing of the finished device is less likely to result in an electrical discontinuity in any of the lines, even if there is some breakage of some filaments forming the mesh. This technique of using a mesh is, for example, of particular use for: (i) forming conductor lines to form capacitors with extended drain conductors and/or COM lines at the same level as the gate lines: (ii) forming back gate lines whose function requires simultaneously applying different voltages to different columns of TFTs; and (iii) forming conductor lines for a touch sensor mechanism.

In addition to any modifications explicitly mentioned above, it will be evident to a person skilled in the art that various other modifications of the described embodiments may be made within the scope of the invention.

1. A device, comprising:
an unplanarised plastic substrate;
an electrically and/or optically functional layer formed on the unplanarised substrate;
a planarisation layer formed over the functional layer; and
at least a first conductor layer and a semiconductor layer formed over the planarization layer,
wherein the first conductor layer defines at least source and drain electrode circuitry for one or more transistor devices, and the semiconductor layer defines semiconductor channels for said one or more transistor devices, and
wherein said electrically and/or optically functional layer comprises a second conductor layer providing gate electrodes for each of the transistor devices.

2. The device according to claim 1, wherein the functional layer exhibits a smaller transmittance than the substrate and planarization layer for light of a wavelength that degrades the semiconductor channels.

3. The device according to claim 2, wherein said light of a wavelength that degrades the semiconductor channels includes visible light; said device further comprises a backlight on the other side of the substrate to the functional layer for the transmission of visible light to optical media located on the opposite side of the semiconductor channels to the backlight and controlled by the transistor devices; and said functional layer is patterned so as to allow the transmission of visible light from the backplane to said optical media in regions other than the semiconductor channels.

4. The device according to claim 3, wherein said optical media is a liquid crystal optical media.

5. The device according to claim 1, wherein the
second conductor layer also extends beneath at least a portion of the drain electrode circuitry for each of said one or more transistors, and is capacitively coupled to the drain electrode circuitry via the planarization layer.

6. The device according to claim 1, wherein said second conductor layer is formed from a mesh of interconnecting conductive filaments.

7. The device according to claim 1, wherein said second conductor layer is patterned into an array of independently addressable gate lines, each gate line extending under the semiconductor channels of a respective column of transistors and comprising a mesh of conductive filaments.

8. The device according to claim 1, wherein said second conductor layer is patterned into an array of islands each isolated from other islands within said second conductor layer, and each island is addressable via one of a plurality of addressing lines extending over the planarization layer.

9. The device according to claim 1, further comprising a third conductor layer formed over the planarization layer on the opposite side of the first conductor layer to the second conductor layer, which third conductor layer defines gate electrode circuitry for said array of transistor devices.

10. The device according to claim 1, wherein the unplanarised substrate has a surface roughness R_{A} greater than 5 nm.

11. The device according to claim 1, wherein the planarisation layer has a lower surface roughness than the surface of the plastic substrate on which the second conductor layer is formed.

12. The device according to claim 1, wherein the first conductor layer comprises source addressing lines.

13. The device according to claim 9, wherein the third conductor layer defines gate lines, and the second conductor layer defines column conductors, each column conductor aligned with a respective one of the gate lines.

14. The device according to claim 13, wherein each of said gate lines provides a first gate electrode for a respective column of thin film transistors, and each of said column conductors provides a second gate electrode for the respective column of transistors.

15. A method of operating a device according to claim 9, comprising: controlling the voltage applied to said gate electrodes defined by the second conductor layer so as to mitigate stress induced in the semiconductor channels by the operation of the gate electrode circuitry.

16. A method of operating a device according to claim 9, comprising: using said gate electrodes defined by the second conductor layer to tune the threshold voltage of the transistor devices, and using said gate electrode circuitry to switch the transistor devices.

17. A method comprising:
providing an unplanarised substrate;
forming an electrically and/or optically functional layer on the unplanarised substrate;
forming a planarisation layer over the functional layer; and
forming a first conductor layer and a semiconductor layer over the planarization layer,
wherein the first conductor layer defines at least source and drain electrode circuitry for one or more transistor devices, and the semiconductor layer defines semiconductor channels for said one or more transistor devices, and
wherein the electrically and/or optically functional layer comprises a second conductor layer providing gate electrodes for each of the transistor devices.

18. The method according to claim 17, wherein the unplanarised substrate has a surface roughness R_{A} greater than 5 nm.

19. The method according to claim 17, wherein the functional layer is a patterned layer.
